(19) United States
(12) Patent Application Publication
(10) Pub. No.: US 2025/0261421 A1
(43) Pub. Date: Aug. 14, 2025

(54) WAFER AND SEMICONDUCTOR DEVICE

(71) Applicant: KABUSHIKI KAISHA TOSHIBA, Tokyo (JP)

(72) Inventors: Ryoma KANEKO, Ota (JP); Seiya TAKEDA, Yokohama (JP); Shinya NUNOUE, Ichikawa (JP); Toshiki HIKOSAKA, Kawasaki (JP)

(73) Assignee: KABUSHIKI KAISHA TOSHIBA, Tokyo (JP)

(21) Appl. No.: 19/017,073

(22) Filed: Jan. 10, 2025

(30) Foreign Application Priority Data
Feb. 9, 2024 (JP) 2024-018935

(51) Int. Cl. H10D 62/854; H10D 30/47; H10D 62/852

(52) U.S. Cl. CPC H10D 62/854; H10D 30/476; H10D 62/852

(57) ABSTRACT

According to one embodiment, a wafer includes a base, a first layer including Al_{z1}Ga_{1-z1}N (0<z1<1), a second layer including Al_{z2}Ga_{1-z2}N (0<z2<z1), a third layer including Al_{z3}Ga_{1-z3}N (0<z3<z2), and a fourth layer. The first layer is between the base and the fourth layer in a first direction. The second layer is between the first layer and the fourth layer in the first direction. The third layer is between the second layer and the fourth layer in the first direction. The fourth layer includes a plurality of first films including Al_{y1}Ga_{1-y1}N (0<y1≤1), and a plurality of second films including Al_{y2}Ga_{1-y2}N (0≤y2<1, y2<y1).

### CROSS-REFERENCE TO RELATED APPLICATIONS

This application is based upon and claims the benefit of priority from Japanese Patent Application No. 2024-018935, filed on Feb. 9, 2024; the entire contents of which are incorporated herein by reference.

### FIELD

Embodiments described herein relate generally to a wafer and a semiconductor device.

### BACKGROUND

For example, improvements in characteristics are desired in semiconductor devices based on wafers including nitrides.

### BRIEF DESCRIPTION OF THE DRAWINGS

FIG. 1 is a schematic cross-sectional view illustrating a wafer according to a first embodiment;

FIGS. 2A and 2B are schematic diagrams illustrating the wafer according to the first embodiment;

FIG. 3 is a graph illustrating the characteristics of the wafer;

FIG. 4 is a graph illustrating the characteristics of the wafer;

FIG. 5 is a graph illustrating the characteristics of the wafer;

FIG. 6 is a schematic cross-sectional view illustrating a semiconductor device according to a second embodiment; and

FIG. 7 is a schematic cross-sectional view illustrating a semiconductor device according to the second embodiment.

### DETAILED DESCRIPTION

According to one embodiment, a wafer includes a base, a first layer including Al_{z1}Ga_{1-z1}N (0<z1<1), a second layer including Al_{z2}Ga_{1-z2}N (0<z2<z1), a third layer including Al_{z3}Ga_{1-z3}N (0<z3<z2), and a fourth layer. The first layer is between the base and the fourth layer in a first direction. The second layer is between the first layer and the fourth layer in the first direction. The third layer is between the second layer and the fourth layer in the first direction. The fourth layer includes a plurality of first films including Al_{y1}Ga_{1-y1}N (0<y1≤1), and a plurality of second films including Al_{y2}Ga_{1-y2}N (0≤y2<1, y2<y1). One of the plurality of first films is provided between one of the plurality of second films and another one of the plurality of second films in the first direction. The one of the plurality of second films is provided between the one of the plurality of first films and another one of the plurality of first films in the first direction. A second carbon concentration in the second layer is higher than a first carbon concentration in the first layer. A third carbon concentration in the third layer is lower than the second carbon concentration. A fourth carbon concentration in the fourth layer is lower than the second carbon concentration.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

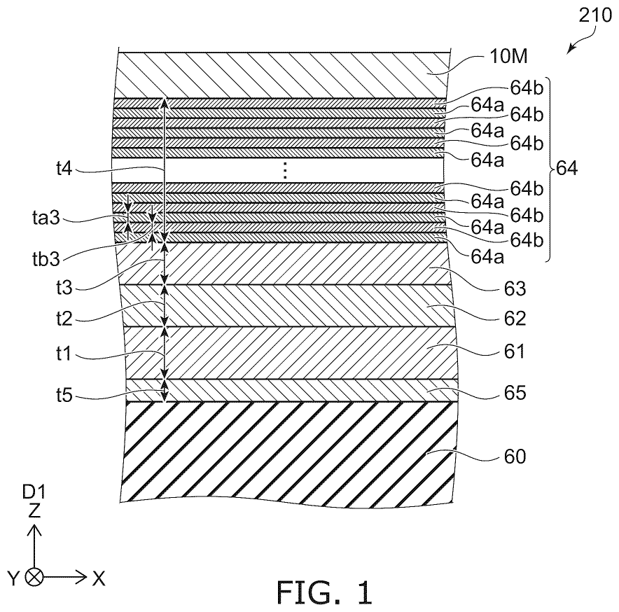

FIG. 1 is a schematic cross-sectional view illustrating a wafer according to a first embodiment.

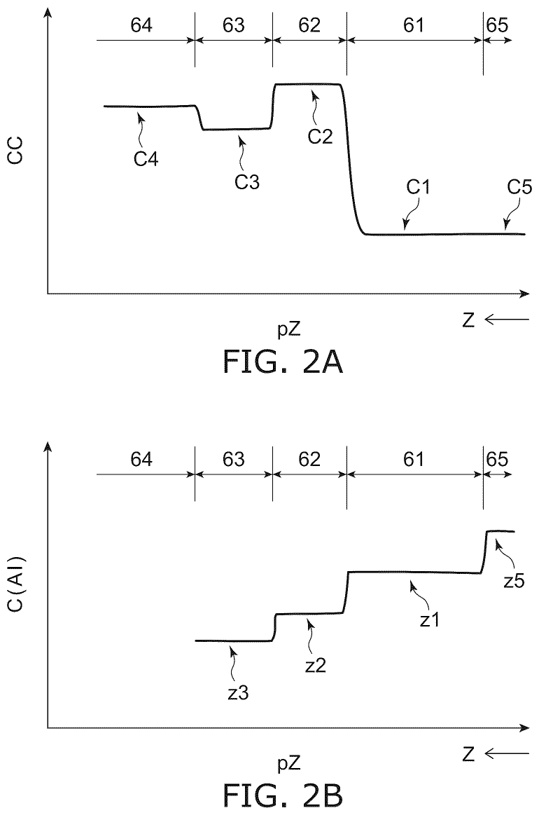

FIGS. 2A and 2B are schematic diagrams illustrating the wafer according to the first embodiment.

As shown in FIG. 1, a wafer 210 according to the embodiment includes a base 60, a first layer 61, a second layer 62, a third layer 63, and a fourth layer 64.

The first layer 61 includes Al_{z1}Ga_{1-z1}N (0<z1<1). The second layer 62 includes Al_{z2}Ga_{1-z2}N (0<z2<z1). The third layer 63 includes Al_{z3}Ga_{1-z3}N (0<z3<z2).

The first layer 61 is between the base 60 and the fourth layer 64 in a first direction D1.

The first direction D1 is defined as a Z-axis direction. One direction perpendicular to the Z-axis direction is defined as an X-axis direction. A direction perpendicular to the Z-axis direction and the X-axis direction is defined as a Y-axis direction. The base 60, the first layer 61, the second layer 62, the third layer 63, and the fourth layer 64 are layered along the X-Y plane.

The second layer 62 is between the first layer 61 and the fourth layer 64 in the first direction D1. The third layer 63 is between the second layer 62 and the fourth layer 64 in the first direction D1.

The fourth layer 64 includes a plurality of first films 64a and a plurality of second films 64b. The plurality of first films 64a include Al_{y1}Ga_{1-y1}N (0<y1≤1). The plurality of second films 64b include Al_{y2}Ga_{1-y2}N (0≤y2<1, y2<y1).

One of the plurality of first films 64a is provided between one of the plurality of second films 64b and another one of the plurality of second films 64b in the first direction D1. One of the plurality of second films 64b is provided between one of the plurality of first films 64a and another one of the plurality of first films 64a in the first direction D1. For example, the first film 64a and the second film 64b may be arranged alternately.

The plurality of first films 64a include Al_{y1}Ga_{1-y1}N (0<y1≤1). The plurality of second films 64b include Al_{y2}Ga_{1-y2}N (0≤y2<1, y2<y1). For example, the plurality of first films 64a may be AlGaN layers or AlN layers. For example, the plurality of second films 64b may be AlGaN layers or GaN layers. The fourth layer 64 is, for example, a superlattice layer.

For example, the second layer 62 is formed on the first layer 61. The third layer 63 is formed on the second layer 62. The fourth layer 64 is formed on the third layer 63. The first layer 61, the second layer 62, the third layer 63, and the fourth layer 64 include, for example, crystals.

For example, the third layer 63 may be in contact with the second layer 62 and the fourth layer 64.

FIGS. 2A and 2B illustrate the carbon concentration profile in the wafer 210. The horizontal axis in FIGS. 2A and 2B is the position pZ in the Z-axis direction. The vertical axis in FIG. 2A is the carbon concentration CC. The vertical axis in FIG. 2B is the Al composition ratio C(Al).

As shown in FIG. 2A, a second carbon concentration C2 in the second layer 62 is higher than a first carbon concentration C1 in the first layer 61. A third carbon concentration C3 in the third layer 63 is lower than the second carbon concentration C2. A fourth carbon concentration C4 in the fourth layer 64 is lower than the second carbon concentration C2.

In the embodiment, the first carbon concentration C1 in the first layer 61 is low. As a result, high flatness can be obtained in the first layer 61. For example, high crystal quality can be obtained in layers formed on the first layer 61.

In the embodiment, the second carbon concentration C2 in the second layer 62 is high. As a result, a high breakdown voltage can be obtained, for example, in a semiconductor device based on the wafer 210.

In the embodiment, the fourth carbon concentration C4 in the fourth layer 64 is lower than the second carbon concentration C2. As a result, leakage current in a semiconductor device based on the wafer 210 is suppressed, for example.

In the embodiment, the third carbon concentration C3 in the third layer 63 is lower than the second carbon concentration C2. As a result, current collapse, for example, in a semiconductor device based on the wafer 210 is suppressed. For example, leakage current is suppressed.

According to the embodiment, a wafer with improved characteristics can be provided. According to the embodiment, a wafer for a semiconductor device whose characteristics can be improved can be provided.

In the embodiment, the third carbon concentration C3 may be lower than the fourth carbon concentration C4. As a result, current collapse is suppressed, for example. For example, stable operation can be easily obtained. Fluctuations in on-resistance can be suppressed.

For example, the fourth carbon concentration C4 may be higher than the first carbon concentration C1. For example, the third carbon concentration C3 may be higher than the first carbon concentration C1. Higher crystal quality can be obtained by lowering the first carbon concentration C1. For example, high flatness can be easily obtained.

For example, the second carbon concentration C2 may be not less than 10 times and not more than 500 times the first carbon concentration C1. For example, the second carbon concentration C2 may be not less than two times and not more than 10 times the fourth carbon concentration C4. For example, the second carbon concentration C2 may be not less than two times and not more than 15 times the third carbon concentration C3.

In the embodiment, the composition ratio z1 may be, for example, not less than 0.6 and less than 0.9. The composition ratio z2 may be, for example, not less than 0.3 and not more than 0.6. The composition ratio z3 may be, for example, not less than 0.1 and not more than 0.3. The composition ratio y1 may be, for example, not less than 0.8 and not more than 1. The composition ratio y2 may be, for example, not less than 0 and not more than 0.4.

As shown in FIG. 1, the first layer 61 has a first thickness t1 in the first direction D1. The second layer 62 has a second thickness t2 in the first direction D1. The third layer 63 has a third thickness t3 in the first direction D1. The fourth layer 64 has a fourth thickness t4 in the first direction D1. In the embodiment, the fourth thickness t4 is preferably smaller than the sum of the first thickness t1, the second thickness t2, and the third thickness t3. Since the fourth thickness t4 of the fourth layer 64 including the plurality of first films 64a and the plurality of second films 64b is small, high efficiency in manufacturing can be obtained. For example, manufacturing in a short time becomes easy.

In the embodiment, the fourth thickness t4 may be smaller than the sum of the second thickness t2 and the third thickness t3. Manufacturing with higher efficiency becomes easier.

As already explained, for example, the third layer 63 may be in contact with the second layer 62 and the fourth layer 64. In this example, the second layer 62 is in contact with the first layer 61. In the embodiment, the Al composition ratio in the first layer 61 may decrease in the direction from the base 60 to the second layer 62.

As shown in FIG. 1, the wafer 210 may further include a fifth layer 65. The fifth layer 65 is provided between the base 60 and the first layer 61 in the first direction D1. For example, the fifth layer 65 is in contact with the base 60 and the first layer 61. For example, the fifth layer 65 is formed on the base 60. For example, the first layer 61 is formed on the fifth layer 65.

The fifth layer 65 includes Al_{z5}Ga_{1-z5}N (z3<z5≤1). The composition ratio z5 is, for example, not less than 0.9 and not more than 1. The composition ratio z5 may be 1. The fifth layer 65 may be, for example, an AlN layer. For example, a fifth carbon concentration C5 in the fifth layer 65 is lower than the second carbon concentration C2. The fifth carbon concentration C5 may be substantially the same as the first carbon concentration C1.

For example, the base 60 may be a silicon substrate. The base 60 may include GaN, SiC, or the like. When the base 60 includes silicon, melt-back etching is suppressed by the fifth layer 65, for example.

In the embodiment, a concentration of Fe in the fifth layer 65 may be less than 1×10¹⁷ cm⁻³. The concentration of Fe in the first layer 61, second layer 62, third layer 63, and fourth layer 64 may be less than 1×10¹⁷ cm⁻³. These layers may substantially not include Fe. For example, it is easy to obtain high crystal quality. For example, high carrier mobility can be easily obtained.

In the embodiment, the first thickness t1 may be, for example, not less than 500 nm and less than 1200 nm. The second thickness t2 may be not less than 500 nm and less than 1200 nm. The third thickness t3 may be not less than 500 nm and less than 1200 nm. Alternatively, the first thickness t1 may be not less than 300 nm and less than 800 nm. The second thickness t2 may be not less than 300 nm and less than 800 nm. The third thickness t3 may be not less than 300 nm and less than 800 nm. The fourth thickness t4 may be not less than 300 nm and less than 800 nm. The fifth thickness t5 may be, for example, not less than 100 nm and not more than 400 nm.

In the embodiment, a thickness ta3 of one of the plurality of first films 64a along the first direction D1 is, for example, not less than 3 nm and not more than 10 nm. A thickness tb3 of one of the plurality of second films 64b along the first direction D1 is, for example, not less than 15 nm and not more than 35 nm. The number of the plurality of first films 64a may be, for example, not less than 17 and not more than 40.

As shown in FIG. 1, the wafer 210 may further include a semiconductor member 10M. The fourth layer 64 is provided between the third layer 63 and the semiconductor member 10M in the first direction D1. For example, the third layer 63 is formed on the second layer 62. The fourth layer 64 is provided on the third layer 63. The semiconductor member 10M is formed on the fourth layer 64.

The semiconductor member 10M includes, for example, Ga and nitrogen. The semiconductor member 10M includes crystals. The semiconductor member 10M includes, for example, GaN. The semiconductor member 10M may function as a functional layer of a semiconductor device.

For example, the first carbon concentration C1 is preferably not less than 1×10¹⁷ cm⁻³ and less than 2×10¹⁸ cm⁻³. For example, the second carbon concentration C2 is preferably not less than 2×10¹⁹ cm⁻³ and not more than 2×10²⁰ cm⁻³. For example, the third carbon concentration is preferably not less than 1×10¹⁸ cm⁻³ and less than 7×10¹⁸ cm⁻³. For example, the fourth carbon concentration is preferably not less than 5×10¹⁸ cm⁻³ and less than 2×10¹⁹ cm⁻³.

As shown in FIG. 2B, in the structure including the fifth layer 65, the first layer 61, the second layer 62, and the third layer 63, the Al composition ratio C (Al) varies from the base 60 to the fourth layer 64.

Examples of the characteristics of the wafer 210 will be described below.

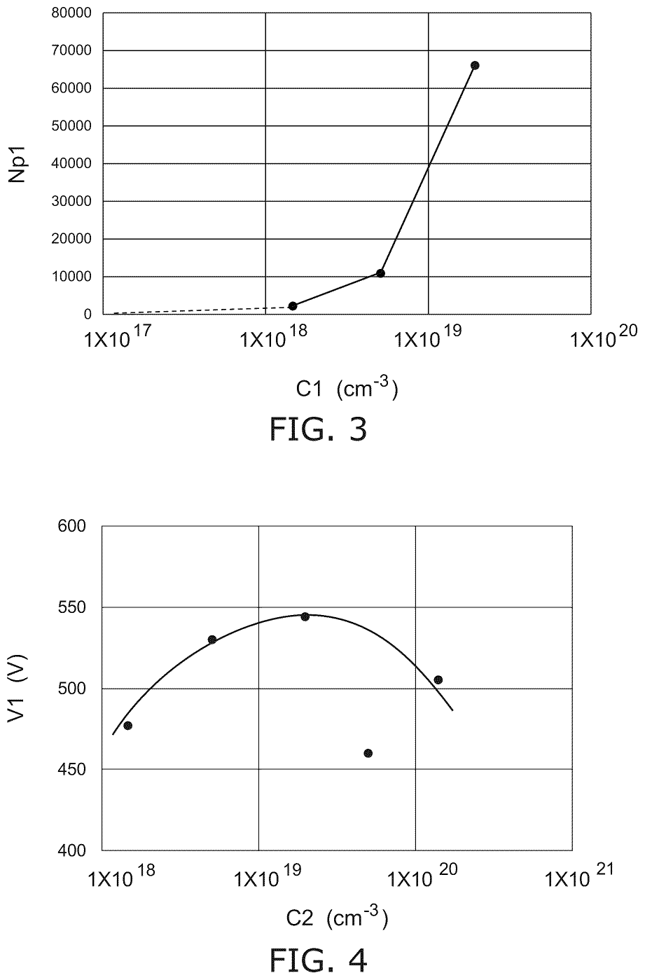

FIG. 3 is a graph illustrating the characteristics of the wafer.

The horizontal axis in FIG. 3 is the first carbon concentration C1 in the first layer 61. The vertical axis is a number Np1 of pits per unit area on a surface of the wafer 210. As can be seen from FIG. 3, when the first carbon concentration C1 is low, the number Np1 of pits is small. As shown in FIG. 3, when the first carbon concentration C1 is 3×10¹⁸ cm⁻³ or less, the number Np1 of pits decreases rapidly. When the first carbon concentration C1 is 1.5×10¹⁸ cm⁻³ or less, the number Np1 of pits further decreases. In the embodiment, for example, it is preferably not less than 1×10¹⁷ cm⁻³ and not more than 1.5×10¹⁸ cm⁻³. Pits can be suppressed. For example, high flatness can be obtained. In the embodiment, it may be not less than 1×10¹⁷ cm⁻³ and less than 2×10¹⁸ cm⁻³.

FIG. 4 is a graph illustrating the characteristics of the wafer.

The horizontal axis in FIG. 4 is the second carbon concentration C2 in the second layer 62. The vertical axis is the pinch-off voltage V1. The pinch-off voltage V1 is a voltage at which the drain current rapidly decreases in a semiconductor device based on the wafer 210. The pinch-off voltage V1 corresponds to, for example, the pinch-off voltage of the two-dimensional electron gas.

As can be seen from FIG. 4, a pinch-off voltage V1 being high is obtained when the second carbon concentration C2 is in the range of not less than 3×10¹⁹ cm⁻³ and not more than 1.2×10²⁰ cm⁻³. Considering the error, it is preferable that the second carbon concentration C2 is not less than 2×10¹⁹ cm⁻³ and not more than 2×10²⁰ cm⁻³. For example, high breakdown voltage can be obtained. Stable operation can be obtained.

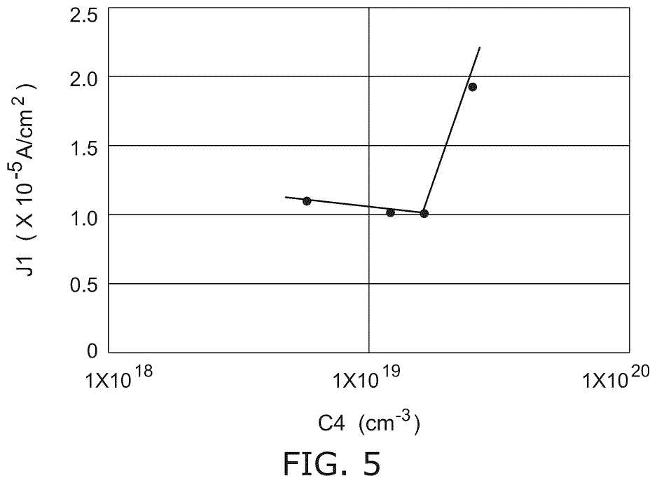

FIG. 5 is a graph illustrating the characteristics of the wafer.

The horizontal axis in FIG. 5 is the fourth carbon concentration C4 in the fourth layer 64. The vertical axis is leakage current density J1. The leakage current density J1 is the density of current flowing between the electrode provided on the semiconductor member 10M and the base 60. As can be seen from FIG. 5, the leakage current density J1 being low is obtained when the fourth carbon concentration C4 is in the range not less than of 5×10¹⁸ cm⁻³ and not more than 1.6×10¹⁹ cm⁻³. In the embodiment, the fourth carbon concentration C4 is preferably 5×10¹⁸ cm⁻³ or more. In the embodiment, the fourth carbon concentration C4 may be not less than 5×10¹⁸ cm⁻³ and less than 2×10¹⁹ cm⁻³. In the embodiment, the fourth carbon concentration C4 may be not less than 5×10¹⁸ cm⁻³ and not more than 1.6×10¹⁹ cm⁻³.

### Second Embodiment

The second embodiment relates to a semiconductor device. The semiconductor device includes the wafer 210 described in connection with the first embodiment and modifications thereof.

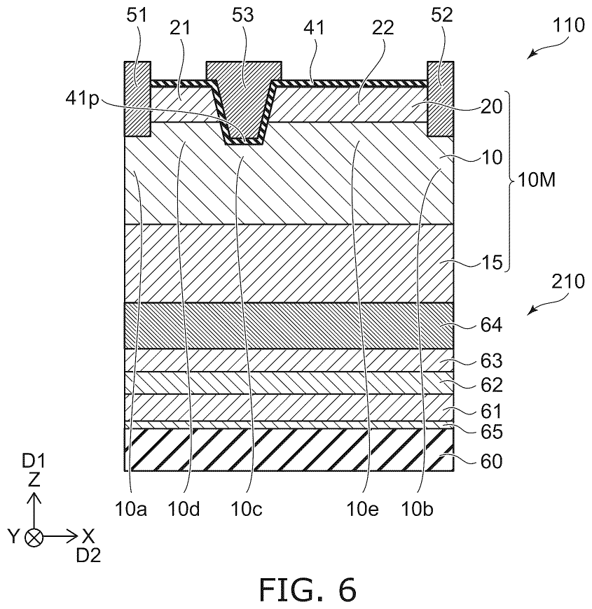

FIG. 6 is a schematic cross-sectional view illustrating a semiconductor device according to the second embodiment.

As shown in FIG. 6, a semiconductor device 110 according to the embodiment includes the wafer 210 according to the first embodiment, the semiconductor member 10M, the first electrode 51, the second electrode 52, and the third electrode 53.

The semiconductor member 10M includes, for example, a first semiconductor layer 10 and a second semiconductor layer 20. The first semiconductor layer 10 includes Alₓ₁Ga₁₋ₓ₁N (0<x1<1). The second semiconductor layer 20 includes Alₓ₂Ga₁₋ₓ₂N (0<x2≤1, x1<x2). The composition ratio x1 may be, for example, not less than 0 and not more than 0.15. The first semiconductor layer 10 is, for example, a GaN layer. The composition ratio x2 may be, for example, more than 0.15 and not more than 0.3.

The second semiconductor layer 20 is, for example, an AlGaN layer.

The first semiconductor layer 10 is provided between the fourth layer 64 and the second semiconductor layer 20.

A second direction D2 from the first electrode 51 to the second electrode 52 crosses the first direction D1. The second direction D2 is, for example, the X-axis direction. A position of the third electrode 53 in the second direction D2 is between a position of the first electrode 51 in the second direction D2 and a position of the second electrode 52 in the second direction D2.

The second semiconductor layer 20 includes a first semiconductor portion 21 and a second semiconductor portion 22. A direction from the first semiconductor portion 21 to the second semiconductor portion 22 is along the second direction D2. The first electrode 51 is electrically connected to the first semiconductor portion 21. The second electrode 52 is electrically connected to the second semiconductor portion 22.

Current flowing between the first electrode 51 and the second electrode 52 is controlled by a potential of the third electrode 53. The potential of the third electrode 53 may be, for example, a potential based on a potential of the first electrode 51. The first electrode 51 functions, for example, as a source electrode. The second electrode 52 functions as a drain electrode. The third electrode 53 functions as a gate electrode. The semiconductor device 110 is, for example, a transistor.

The first semiconductor layer 10 includes a region facing the second semiconductor layer 20. A carrier region is formed in this region. The carrier region is, for example, a two-dimensional electron gas. The semiconductor device 110 is, for example, a HEMT (High Electron Mobility Transistor).

In the semiconductor device 110 according to the embodiment, for example, a high breakdown voltage can be obtained. For example, low leakage current can be obtained. For example, by the high crystallinity, low on-resistance is obtained. For example, it is easy to obtain a large on-current. According to the embodiment, a semiconductor device with improved characteristics can be provided.

As shown in FIG. 6, in this example, at least a part of the third electrode 53 is provided between the first semiconductor portion 21 and the second semiconductor portion 22 in the second direction D2. The third electrode 53 is, for example, a recessed gate electrode. For example, a high threshold voltage can be obtained. For example, normally-off operation is obtained.

For example, the first semiconductor layer 10 includes a first partial region 10a, a second partial region 10b, a third partial region 10c, a fourth partial region 10d, and a fifth partial region 10e. A direction from the first partial region 10a to the first electrode 51 is along the first direction D1. A direction from the second partial region 10b to the second electrode 52 is along the first direction D1. A direction from the third partial region 10c to the third electrode 53 is along the first direction D1.

A position of the fourth partial region 10d in the second direction D2 is between a position of the first partial region 10a in the second direction D2 and a position of the third partial region 10c in the second direction D2. A position of the fifth partial region 10e in the second direction D2 is between the position of the third partial region 10c in the second direction D2 and a position of the second partial region 10b in the second direction D2.

A direction from the fourth partial region 10d to the first semiconductor portion 21 is along the first direction D1. A direction from the fifth partial region 10e to the second semiconductor portion 22 is along the first direction D1. In this example, a part of the third electrode 53 is between the fourth partial region 10d and the fifth partial region 10e in the second direction D2. A high threshold voltage can be obtained. For example, normally-off operation can be stably obtained.

As shown in FIG. 6, the semiconductor device 110 may further include a first insulating member 41. The first insulating member 41 includes a first insulating portion 41p. The first insulating portion 41p is provided between the third electrode 53 and the semiconductor member 10M. The first insulating portion 41p functions, for example, as a gate insulating film.

As shown in FIG. 6, the semiconductor member 10M may further include an intermediate layer 15. The intermediate layer 15 is provided between the fourth layer 64 and the first semiconductor layer 10. The intermediate layer 15 includes, for example, Alₓ₃Ga₁₋ₓ₃N (0≤x1<1, x3<x2). The composition ratio x3 may be, for example, not less than 0 and not more than 0.25. The intermediate layer 15 is, for example, a GaN layer.

For example, the concentration of carbon in the intermediate layer 15 is higher than the concentration of carbon in the first semiconductor layer 10. Alternatively, the intermediate layer 15 includes carbon and the first semiconductor layer 10 does not include carbon. By the intermediate layer 15 including carbon, it becomes easy to obtain high carrier mobility, for example.

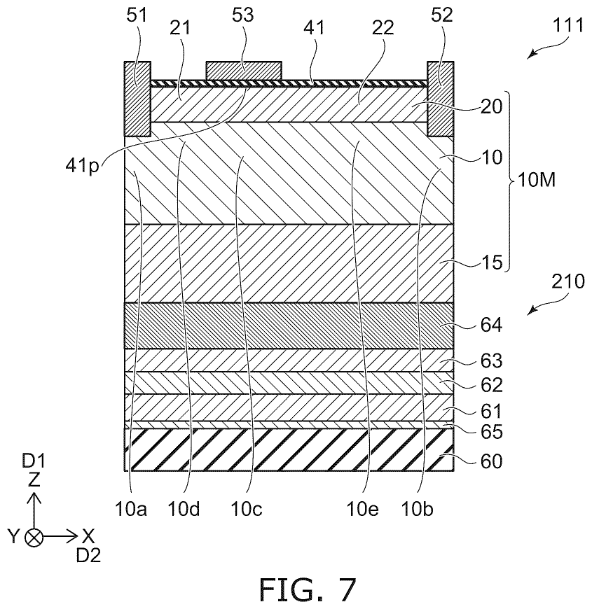

FIG. 7 is a schematic cross-sectional view illustrating a semiconductor device according to the second embodiment.

As shown in FIG. 7, a semiconductor device 111 according to the embodiment includes the wafer 210 according to the first embodiment, the semiconductor member 10M, the first electrode 51, the second electrode 52, and the third electrode 53. In the semiconductor device 111, the third electrode 53 does not overlap the second semiconductor layer 20 in the second direction D2. The configuration of the semiconductor device 111 other than this may be the same as the configuration of the semiconductor device 110.

In the semiconductor device 111, for example, normally-on operation can be obtained. In the semiconductor device 111, the first insulating member 41 may be omitted. The semiconductor device 111 may be used as a high frequency switching element, for example.

In the embodiment, information regarding the shape of the nitride region, etc. can be obtained, for example, by electron microscopic observation. Information regarding the composition and element concentration in the nitride region can be obtained by, for example, EDX (Energy Dispersive X-ray Spectroscopy) or SIMS (Secondary Ion Mass Spectrometry). Information regarding the composition in the nitride region may be obtained, for example, by reciprocal space mapping.

The embodiments may include the following technical proposals:

### (Technical Proposal 1)

A wafer, comprising:
a base;
a first layer including Al_{z1}Ga_{1-z1}N (0<z1<1);
a second layer including Al_{z2}Ga_{1-z2}N (0<z2<z1);
a third layer including Al_{z3}Ga_{1-z3}N (0<z3<z2); and
a fourth layer,
the first layer being between the base and the fourth layer in a first direction,
the second layer being between the first layer and the fourth layer in the first direction,
the third layer being between the second layer and the fourth layer in the first direction,
the fourth layer including
   a plurality of first films including Al_{y1}Ga_{1-y1}N (0<y1≤1), and
   a plurality of second films including Al_{y2}Ga_{1-y2}N (0≤y2<1, y2<y1),
one of the plurality of first films being provided between one of the plurality of second films and another one of the plurality of second films in the first direction,
the one of the plurality of second films being provided between the one of the plurality of first films and another one of the plurality of first films in the first direction,
a second carbon concentration in the second layer being higher than a first carbon concentration in the first layer,
a third carbon concentration in the third layer being lower than the second carbon concentration, and
a fourth carbon concentration in the fourth layer being lower than the second carbon concentration.

### (Technical Proposal 2)

The wafer according to Technical proposal 1, wherein
the third carbon concentration is lower than the fourth carbon concentration.

### (Technical Proposal 3)

The wafer according to Technical proposal 1 or 2, wherein
the fourth carbon concentration is higher than the first carbon concentration.

### (Technical Proposal 4)

The wafer according to any one of Technical proposals 1-3, wherein
the second carbon concentration is not less than 10 times and not more than 500 times the first carbon concentration.

### (Technical Proposal 5)

The wafer according to any one of Technical proposals 1-4, wherein
the second carbon concentration is not less than 2 times and not more than 10 times the fourth carbon concentration.

### (Technical Proposal 6)

The wafer according to any one of Technical proposals 1-5, wherein
the first layer has a first thickness in the first direction,
the second layer has a second thickness in the first direction,
the third layer has a third thickness in the first direction,
the fourth layer has a fourth thickness in the first direction, and
the fourth thickness is smaller than a sum of the first thickness, the second thickness, and the third thickness.

### (Technical Proposal 7)

The wafer according to Technical proposal 6, wherein
the fourth thickness is smaller than a sum of the second thickness and the third thickness.

### (Technical Proposal 8)

The wafer according to any one of Technical proposals 1-7, wherein
the third layer is in contact with the second layer and the fourth layer.

### (Technical Proposal 9)

The wafer according to any one of Technical proposals 1-8, further comprising:
a fifth layer including Al_{z5}Ga_{1-z5}N (z3<z5≤1),
the fifth layer being provided between the base and the first layer.

### (Technical Proposal 10)

The wafer according to Technical proposal 9, wherein
the z5 is not less than 0.9 and not more than 1.

### (Technical Proposal 11)

The wafer according to Technical proposal 9 or 10, wherein
a concentration of Fe in the fifth layer is less than 1×10¹⁷ cm⁻³.

### (Technical Proposal 12)

The wafer according to any one of Technical proposals 1-11, wherein
the z1 is not less than 0.6 and less than 0.9,
the z2 is not less than 0.3 and less than 0.6,
the z3 is not less than 0.1 and not more than 0.3,
the y1 is not less than 0.8 and not more than 1, and
the y2 is not less than 0 and not more than 0.4.

### (Technical Proposal 13)

The wafer according to any one of Technical proposals 1-12, wherein
a concentration of Fe in the first layer, the second layer, the third layer, and the fourth layer is less than 1×10¹⁷ cm⁻³.

### (Technical Proposal 14)

The wafer according to any one of Technical proposals 1-13, wherein
the first carbon concentration is not less than 1×10¹⁷ cm⁻³ and less than 2×10¹⁸ cm⁻³.

### (Technical Proposal 15)

The wafer according to any one of Technical proposals 1-14, wherein
the second carbon concentration is not less than 2×10¹⁹ cm⁻³ and not more than 2×10²⁰ cm⁻³.

### (Technical Proposal 16)

The wafer according to any one of Technical proposals 1-15, wherein
the third carbon concentration is not less than 1×10¹⁸ cm⁻³ and less than 7×10¹⁸ cm⁻³.

### (Technical Proposal 17)

The wafer according to any one of Technical proposals 1-16, wherein
the fourth carbon concentration is not less than 5×10¹⁸ cm⁻³ and less than 2×10¹⁹ cm⁻³.

### (Technical Proposal 18)

The wafer according to any one of Technical proposals 1-17, further comprising:
a semiconductor member including Ga and nitrogen,
the fourth layer being provided between the third layer and the semiconductor member in the first direction.

### (Technical Proposal 19)

A semiconductor device, comprising:
the wafer according to any one of Technical proposals 1-17;
a semiconductor member;
a first electrode;
a second electrode; and
a third electrode,
the semiconductor member including
   a first semiconductor layer including Alₓ₁Ga₁₋ₓ₁N (0≤x1<1), and
   a second semiconductor layer including Alₓ₂Ga₁₋ₓ₂N (0<x2≤1, x1<x2),
the first semiconductor layer being provided between the fourth layer and the second semiconductor layer,
a second direction from the first electrode to the second electrode crossing the first direction,
a position of the third electrode in the second direction being between a position of the first electrode in the second direction and a position of the second electrode in the second direction,
the second semiconductor layer including a first semiconductor portion and a second semiconductor portion,
a direction from the first semiconductor portion to the second semiconductor portion being along the second direction,
the first electrode being electrically connected to the first semiconductor portion, and
the second electrode being electrically connected to the second semiconductor portion.

### (Technical Proposal 20)

The semiconductor device according to Technical proposal 19, wherein
at least a part of the third electrode is provided between the first semiconductor portion and the second semiconductor portion in the second direction.

According to the embodiment, it is possible to provide a wafer and a semiconductor device whose characteristics can be improved.

In the specification of the application, the term “electrically connected state” includes a state in which a plurality of conductors are physically in contact with each other and a current flows between the plurality of conductors. The “state of being electrically connected” includes a state in which another conductor is inserted between the plurality of conductors and a current flows between the plurality of conductors.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the wafers and the semiconductor devices such as bases, layers, electrodes, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all wafers and all semiconductor devices practicable by an appropriate design modification by one skilled in the art based on the wafers and the semiconductor devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A wafer, comprising:
a base;
a first layer including Al_{z1}Ga_{1-z1}N (0<z1<1);
a second layer including Al_{z2}Ga_{1-z2}N (0<z2<z1);
a third layer including Al_{z3}Ga_{1-z3}N (0<z3<z2); and
a fourth layer,
the first layer being between the base and the fourth layer in a first direction,
the second layer being between the first layer and the fourth layer in the first direction,
the third layer being between the second layer and the fourth layer in the first direction,
the fourth layer including
a plurality of first films including Al_{y1}Ga_{1-y1}N (0<y1≤1), and
a plurality of second films including Al_{y2}Ga_{1-y2}N (0≤y2<1, y2<y1),
one of the plurality of first films being provided between one of the plurality of second films and another one of the plurality of second films in the first direction,
the one of the plurality of second films being provided between the one of the plurality of first films and another one of the plurality of first films in the first direction,
a second carbon concentration in the second layer being higher than a first carbon concentration in the first layer,
a third carbon concentration in the third layer being lower than the second carbon concentration, and
a fourth carbon concentration in the fourth layer being lower than the second carbon concentration.

2. The wafer according to claim 1, wherein
the third carbon concentration is lower than the fourth carbon concentration.

3. The wafer according to claim 1, wherein
the fourth carbon concentration is higher than the first carbon concentration.

4. The wafer according to claim 1, wherein
the second carbon concentration is not less than 10 times and not more than 500 times the first carbon concentration.

5. The wafer according to claim 1, wherein
the second carbon concentration is not less than 2 times and not more than 10 times the fourth carbon concentration.

6. The wafer according to claim 1, wherein
the first layer has a first thickness in the first direction,
the second layer has a second thickness in the first direction,
the third layer has a third thickness in the first direction,
the fourth layer has a fourth thickness in the first direction, and
the fourth thickness is smaller than a sum of the first thickness, the second thickness, and the third thickness.

7. The wafer according to claim 6, wherein
the fourth thickness is smaller than a sum of the second thickness and the third thickness.

8. The wafer according to claim 1, wherein
the third layer is in contact with the second layer and the fourth layer.

9. The wafer according to claim 1, further comprising:
a fifth layer including Al_{z5}Ga_{1-z5}N (z3<z5≤1),
the fifth layer being provided between the base and the first layer.

10. The wafer according to claim 9, wherein
the z5 is not less than 0.9 and not more than 1.

11. The wafer according to claim 9, wherein
a concentration of Fe in the fifth layer is less than 1×10¹⁷ cm⁻³.

12. The wafer according to claim 1, wherein
the z1 is not less than 0.6 and less than 0.9,
the z2 is not less than 0.3 and less than 0.6,
the z3 is not less than 0.1 and not more than 0.3,
the y1 is not less than 0.8 and not more than 1, and
the y2 is not less than 0 and not more than 0.4.

13. The wafer according to claim 1, wherein
a concentration of Fe in the first layer, the second layer, the third layer, and the fourth layer is less than 1×10¹⁷ cm⁻³.

14. The wafer according to claim 1, wherein
the first carbon concentration is not less than 1×10¹⁷ cm⁻³ and less than 2×10¹⁸ cm⁻³.

15. The wafer according to claim 1, wherein
the second carbon concentration is not less than 2×10¹⁹ cm⁻³ and not more than 2×10²⁰ cm⁻³.

16. The wafer according to claim 1, wherein
the third carbon concentration is not less than 1×10¹⁸ cm⁻³ and less than 7×10¹⁸ cm⁻³.

17. The wafer according to claim 1, wherein
the fourth carbon concentration is not less than 5×10¹⁸ cm⁻³ and less than 2×10¹⁹ cm⁻³.

18. The wafer according to claim 1, further comprising:
a semiconductor member including Ga and nitrogen, the fourth layer being provided between the third layer and the semiconductor member in the first direction.

19. A semiconductor device, comprising:
the wafer according to claim 1;
a semiconductor member;
a first electrode;
a second electrode; and
a third electrode,
the semiconductor member including
a first semiconductor layer including Alₓ₁Ga₁₋ₓ₁N (0≤x1<1), and
a second semiconductor layer including Alₓ₂Ga₁₋ₓ₂N (0<x2≤1, x1<x2),
the first semiconductor layer being provided between the fourth layer and the second semiconductor layer,
a second direction from the first electrode to the second electrode crossing the first direction,
a position of the third electrode in the second direction being between a position of the first electrode in the second direction and a position of the second electrode in the second direction,
the second semiconductor layer including a first semiconductor portion and a second semiconductor portion,
a direction from the first semiconductor portion to the second semiconductor portion being along the second direction,
the first electrode being electrically connected to the first semiconductor portion, and
the second electrode being electrically connected to the second semiconductor portion.

20. The device according to claim 19, wherein
at least a part of the third electrode is provided between the first semiconductor portion and the second semiconductor portion in the second direction.
